(19) United States
(12) Patent Application Publication
(10) Pub. No.: US 2011/0189600 A1
(43) Pub. Date: Aug. 4, 2011

(54) METHOD FOR AUTOMATED CONTROL OF PROCESSING PARAMETERS

(76) Inventors: Lars Plumer, Herzberg am Harz (DE); Pavel Korolik, Petach Tikva (IL); Danny Koifman, Holon (IL); Harald Baumann, Osterode/Harz (DE); Bernd Strehmel, Berlin (DE)

(21) Appl. No.: 12/696,088

(22) Filed: Jan. 29, 2010

(51) Int. Cl. G03F 7/20

(52) U.S. Cl. 430/30

(57) ABSTRACT

The invention relates to processing imaged precursors such as lithographic printing plates. The invention relates specifically to adjusting a processing device for optimal processing performance using a plate recognition system that includes a senseing and authenication subsystem. The processor is automated to make adjustments according to the information provided.

### CROSS REFERENCE TO RELATED APPLICATIONS

This application relates to commonly assigned, copending U.S. application Ser. No. ______ (Docket No. 96067DPS), filed ______, entitled: “PLATE RECOGNITION SYSTEM FOR AUTOMATED CONTROL OF PROCESSING PARAMETERS” and U.S. application Ser. No. ______ (Docket No. 96066DPS), filed ______, entitled: “PROCESSOR SYSTEM WITH PROVISION FOR AUTOMATED CONTROL OF PROCESSING PARAMETERS” each hereby incorporated by reference.

### BACKGROUND OF THE INVENTION

In the printing industry a wide variety of printing methods are employed. Printing methods such as lithographic, flexographic, screen and gravure printing commonly involve preparing an image-bearing printing surface before commencing printing. Such printing surfaces are often prepared in an imaging device which uses an imagewise addressable radiation source to selectively convert or transform areas of a printing precursor. In some cases the printing surface is directly ready for use following imagewise conversion. In most cases further processing is required. Processing may include further exposure to radiation, heating, chemical development, chemical etching, a variety of other processes or combination thereof.

In other imaging industries such as the direct imaging of printed circuit boards, imaging devices are commonly coupled with a processor of some description for further processing or development of the imaged article. In the graphic arts industry, imaging and processing steps are usually performed by separate equipment, often provided by different manufacturers. For example, lithographic plates, and more particularly thermal lithographic plates are typically imaged in platesetter devices which use high power radiation sources such as lasers for imaging. After imaging, plates are removed from the platesetter and either manually or automatically conveyed to a processor. For negative working thermal plates, processing typically includes a preheat step, which the plate is uniformly heated to crosslink imaged areas, followed by development in a chemical solution that removes non-imaged areas. The plates may be post-baked to improve their run length on press. It is important to heat plates evenly during processing. The required preheat consistency over the plate surface for a negative working thermal plate is preferably in the range of 5° C.-10° C. and most preferably less than 2° C. It is also important to maintain the plate precursors in good condition for imaging.

U.S. Pat. No. 6,550,989 describes an integrated processor which has a pre-heat oven, a developer section, and an optional post-bake section. Preheat is controlled in one embodiment by varying the speed with which plates pass through the preheat section or the disposition of heating elements in response to a trigger such as the plate entering the preheat section. Further measurements of the plate precursor such as width provide additional control inputs for maintaining even heating.

U.S. Pat. No. 7,229,241 discloses an automatic plate feeding system for loading plates of various sizes into a printing plate imaging device, which includes a plurality of trays staggered one on top of the other is provided. At least two of the trays contain plates of different sizes stacked with their sensitive side downward. Separation papers are interposed between the plates. The automatic plate feeding system includes suction cups, which touch the non-sensitive surface of the plate, and a loading mechanism for loading plates from the trays and feeding the loaded plates to the imaging device. Nothing was mentioned about plate recognition.

EP 1055621 discloses an automatic plate feeding system for loading plates of various sizes into a printing plate imaging device, which includes a plurality of trays staggered one on top of the other, wherein at least two of a plurality of trays contain plates of different sizes, the plates having separation papers interposed there between and an arm mechanism for loading plates from the plurality of trays and feeding the loaded plates to the imaging device. Nothing was mentioned about automatic plate recognition.

U.S. Pat. No. 4,295,039 discloses a method and apparatus for identifying an individual holder (person) of an unalterable charge card-like device (CARD) at a utilization terminal (U/I Terminal) wherein a unique user entered key (asserted key K sub. A) is handled in a highly secure manner. Nothing was mentioned about plate recognition.

There remains a need for a better apparatus and methods for processing imaged articles. There is a particular need for such apparatus and methods which can automatically determine if a plate precursor and/or the related processor are compatible and the plate precursor is ready for imaging. The printing industry has special need for such apparatus and methods.

### SUMMARY OF THE INVENTION

One aspect of the invention provides a method to determine if a plate precursor is ready and prepared to be imaged with an imaging device and processed using a processor having a controller which adjusts the processor operation in accordance with information transferred from the imaging device to the processor. In another aspect of the invention the processor transfers information to the imaging device to enable adjustment to the imaging process and/or scheduling of imaging jobs according to conditions pertaining to the plate precursor and related processor, as well as the imaging information.

Another aspect of the invention provides apparatus for imaging and processing precursors. The apparatus includes an imaging device, a processor and means for transferring information about imaged precursors imaged by the imaging device to the processor.

This invention is useful for making printing plates such as lithographic plates and flexographic plates with platesetters (CtP systems) preferably equipped with an automatic loading system.

Further aspects of the invention and features and advantages of specific embodiments of the invention are set out below.

### BRIEF DESCRIPTION OF THE DRAWINGS

In drawings which illustrate non-limiting embodiments of the invention:

FIG. 1 is a schematic depiction of an imaging device and processor according to the present invention.

FIG. 2 is one embodiment of a method according to the present invention

FIGS. 3-7 are various embodiments of systems according to the present invention for automatic recognition of shelf life.

FIG. 8 is an embodiment of a system according to the present invention for automatic exposure energy correction.

FIG. 9 is an embodiment of a system according to the present invention for reading plate identity.

FIG. 10 is an embodiment of a system according to the present invention for adjustment of processor speed to plate type.

FIG. 11 is an embodiment of a system according to the present invention for overcoming problems on anodization on the plate.

### DETAILED DESCRIPTION OF THE INVENTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive, sense. This invention is described in relation to a system including an imaging device that is able to image a precursor (such as a media to be imaged) and a processor for processing the precursor. Processing parameters are adjusted according to information supplied to the processor by the imaging device. The imaging device may include an image-wise addressable radiation source, an imaging bed of any suitable configuration for holding the precursor, a suitable mechanism for scanning the radiation source across the precursor, and mechanisms for handling, loading and unloading the precursor. An internal or external imaging controller or combination thereof, receives image data and controls the functions of the imaging device. Note that in one preferred embodiment the imaging controller is separate from the controller to control the processor parameters. That controller is hereafter the controller referred to. Such systems for imaging lithographic, flexographic, screen and gravure printing forms are well known in the art and range from devices that require manual precursor handling to fully automated machines capable of handling multiple precursor sizes and types in cassettes or other storage that are automatically selected and loaded. One such system is described in U.S. Pat. No. 7,440,123, entitled “Adaptive Printing”, which is hereby incorporated by reference.

The term “precursor”, also known as a “plate precursor”, is used herein to refer to an object having a surface that can be imagewise exposed to form a pattern thereon. The surface may be coated with an imageable coating. The coating may be on a metal or synthetic substrate. The substrate may, for example, comprise a flat plate or a cylindrical sleeve substrate. The term “printing surface” is used herein to refer to the specific instance where the precursor is to be used in a printing operation.

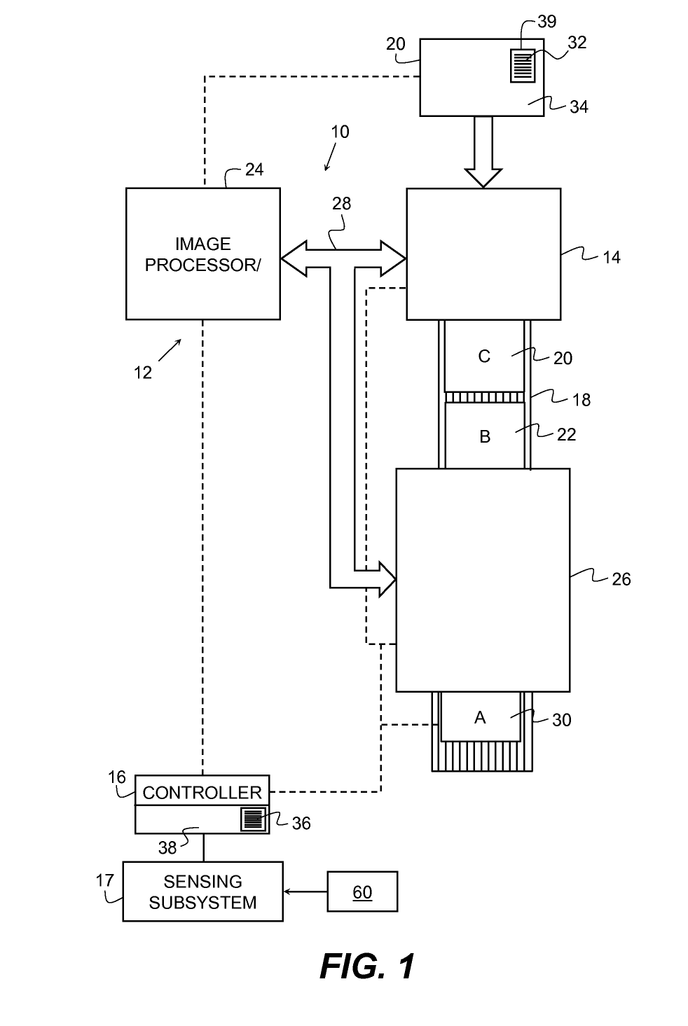

FIG. 1 illustrates one embodiment of a plate processor system including a plate recognition system 10. Shown is an imaging device 12 having an imaging engine 14 and a controller 16. The controller in communication to a sensing, subsystem 17 has access to plate recognition system information from the plate recognition system including information that is used to identify types of plate precursors, with which imaging device 12 and the plate recognition system can use to determine if the plate precursor is ready and/or desirable to be imaged. This information can be, for example, being stored in data storage of any kind accessible to controller 16. The information may include a table or list of precursor parameters. The information may include precursor type, length, width, thickness, exposure sensitivity, exposure delivered, and data about an image to be imparted to the precursor by the imaging device. Types of imaging devices include external or internal drum imaging devices, violet or thermal, LDA or light valves.

A conveyor 18 receives one or more pre-imaged precursors 20, which may be grouped in batches with similar characteristics. Precursors 22 are imaged by an imaging engine 24, thus becoming imaged precursors 22, and transported to a processor 26. Processor 26 can have one or more sections (not shown) for 28 processing the precursor. Processor 26 may include a processing line. In one specific embodiment of the invention for use with lithographic printing plates the processor 26 can have a preheat oven section and a chemical developer section. A processed printing surface 30 then exits the processor 26 and is either manually or automatically conveyed to a printing press. Note that both the pre-imaged precursors 20, either individually or as a batch, can be associated with one or more codes 32 that will be discussed in greater detail below. Alternatively the codes could be associated with the imaged precursors 22 and even be part of the image. The code does not have to be a readable code as will be discussed below.

The controller 16 communicates with imaging engine 14 via a communication path 28 that may comprise any suitable data communication path such as, for example, one or more signal lines, a signal bus, an optical fiber, a wireless link, an optical link or any other path for transferring information. The communication path can also be used to permit communication between controller 16, the processor 26 and the sensing 17 and authentication subsystem 62. These communications may be carried on the same pathway or on a separate pathway from communications between controller 16 and imaging engine 34. Those skilled in the art will understand that any of a wide variety of communications technologies may be used to provide suitable communication between controller 16, and other subsystems. The controller functions may be moved from one device to another without changing the principles of operation of the system or departing from the invention. The communication path transfers information related to the precursors on a continuous or plate-by-plate basis. The information transferred is of use to processor 26 in controlling functions related to further exposure steps, heating steps, development steps and any other processor functions including replenishment of developer chemical solutions. Various embodiments and examples are discussed below in greater detail.

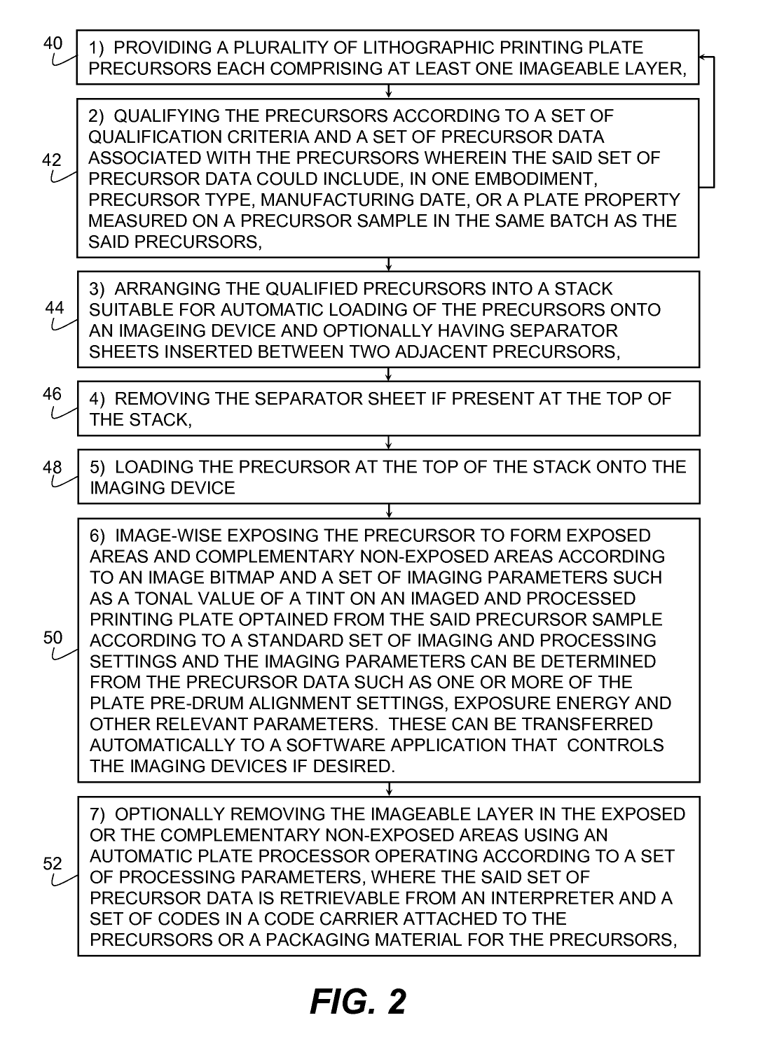

FIG. 2 illustrates the steps to complete a method to enable the plate processor system for a plate system to automatically control various processing parameters. The method for preparing lithographic printing plates starts by providing a plurality of lithographic printing plate precursors 40 each including at least one imageable layer 34 and then grouping the precursors, also referred to as qualifying the precursors, according to a set of qualification criteria 36a and a set of precursor data 36b associated with the precursors 42. This set of precursor data is retrievable from an interpreter 38 (shown in FIG. 1 with the set of qualification criteria 36a and the set of precursor data 36b identified therein) using interpreter software, hereafter sometimes referred to as simply the interpreter. The set of codes 32 can be associated with a code carrier 39 attached to the precursors or a packaging material for the precursors.

The above steps are repeated until the qualified precursors become available to proceed to arrange the qualified precursors into a stack suitable for automatic loading of the precursors onto an imaging device 44 and optionally having separator sheets inserted between two adjacent precursors. Then the separator sheet, if present at the top of the stack, is removed 46 and the qualified precursor(s) are loaded 48 at the top of the stack onto the imaging device and are image-wise exposed 50 to form exposed areas and complementary non-exposed areas according to an image bitmap and a set of imaging parameters. Optionally the imageable layer in the exposed or the complementary non-exposed areas can be removed 52 using an automatic plate processor operating according to a set of processing parameters. These last three to four steps are repeated at least once.

In one embodiment the plate could be loaded by positioning the precursor relative to the plate leading edge on a certain distance from each edge, for example x [mm]. The allowed position variation of the precursor in each plate due to skew, tilt and twist of the plate and also production tolerances no more than +/−3 [mm] relative to x measurement. The sensor readings can be relative to the position of the precursor. Exceeding from the allowed precursor position might cause the sensor readings to be different due to bigger dispersals, longer path of the light to go from the sensor's emitter to the precursor and back to the sensors' reflector yielding in lower energy that represents deviation from desired position. In this case the x measurement is defined according to the physical position of the planned sensor inside the machine.

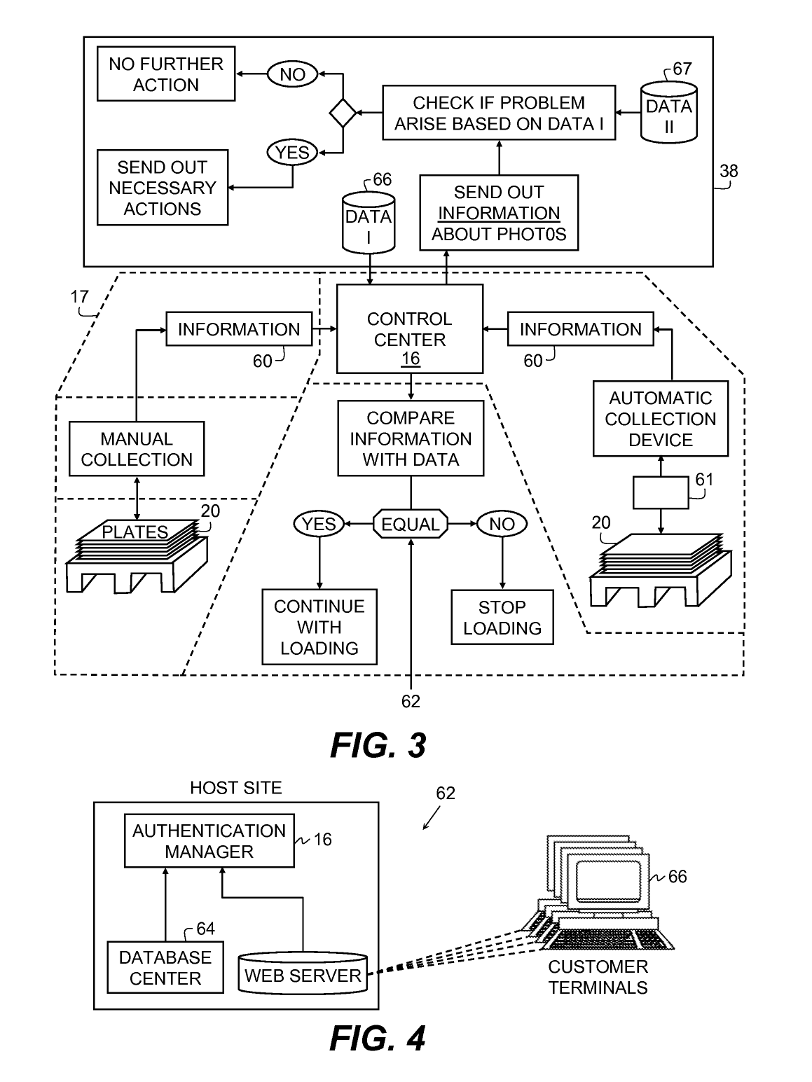

FIGS. 3 and 4 shows the plate recognition system 10 in greater detail. FIG. 3 shows a sensing subsystem 17 and portions of the plate recognition system 10 shown in FIG. 1 including the plate precursors 20 and the interpreter 38. The sensing subsystem 17 collects and forwards plate recognition system information 60, hereafter referred to simply as information 60. The information includes information that can be recognized by the sensing subsystem 17 of the plate recognition system by a variety of means that will be discussed below in greater detail. For example the information can includes positioning, imaging, processing and dimensional information about the plate precursor that can be used to determine if the imaging information to be imaged on the plate precursor can be positioned on each printing plate precursor. In one embodiment the plate recognition system information 60 is located on each plate box or on each plate pallet and in other embodiments the information is actually located adjacent and/or on the plate. The information 60 is written or displayed in such a way that it can be recognized by a plate recognition system, often referred to as a reader, by means that include one or more bar codes, RFID tags, holographic codes, printed codes including letters and numbers or spectral information (colored areas) and other recognizable methods. In other instances the information may be actually a characteristic of the plate that can be independently sensed and then the sensed information 60 is written as a recognizable code or displayed in such a way that it can be recognized by a plate recognition system independently or in conjunction with other plate recognition system information 60 located on each plate box or on each plate pallet. The codes can include alphanumerical strings as well as other visible and non-visual codes. The codes just need to be detectable, so even codes that are not written, such as chemical codes could be useful. The code carriers include Barcodes, RFIDs, holograms, explicitly printed texts, similar to those used in security badges and electronic postage as well as non-visible ones. In preferred embodiments the one embodiment a bar code is most preferred in this embodiment.

The reader 61 can be based on current technology such as a bar code scanner, a RFID tag reader, a sensor capable of identifying automatically holographic information, a video camera system combined with software capable to identify letter/number codes, spectral sensors capable of analyzing spectral data, a CCD sensor or even manually insertion of a barcode information by the operator as long as it can read or sense the code and/or code carrier. The plate recognition system interacts with the plurality of plates or with every single plate fully automatically, partially automatically or manually.

FIG. 4 shows an authentication subsystem 62 of the plate recognition system 10 shown in FIG. 3. The authentication subsystem 62 authenticates the collected information 60 and forwards it to appropriate parts of the plate recognition system 10 or to external related systems used to confirm the process. The authentication subsystem 62 will store the data received from the sensing subsystem 17 on a local or remote database site 64. In one embodiment the authentication subsystem 62 will compare this data 60 to one or more of source data 66 received from the consumable manufacturer's computer systems and collected data 67 that could have been previously stored. Applicable authentication rules are added to the software that will perform the comparison. Details about and schematic diagrams of certain embodiments of the invention are described below.

The plate recognition system prevents or improves the processing of plates including, but not limited to the elimination of using wrong printing plates, the elimination of using printing plates outside of their shelf life, by effectively adjusting the exposure energy of every plate batch based on measurements made by the plate precursor manufacturer resulting in more consistent results. The system will also allow the transfer of plate dimension information into the platesetters which allows avoiding sophisticated means in the platesetter to measure the plate dimensions, the simplification of recording of plate stock and initiation of new plate orders, of remote support of the printing plate consumer by the printing plate precursor manufacturer, and of imaging device self diagnostic sequences. The system reduces printing plates loading downtime of imaging device due to the diminution of exposure quality problems due to incompatibility between the resolution of the source file and maximal screening level of the plate type, the diminution of process quality problems due to incompatibility between the speed of the processor and the type of plate and saving time to adjust the speed of the processor and the diminution of plate loading problems originating of false identification of plate as a slip sheet, anodize and emulsion.

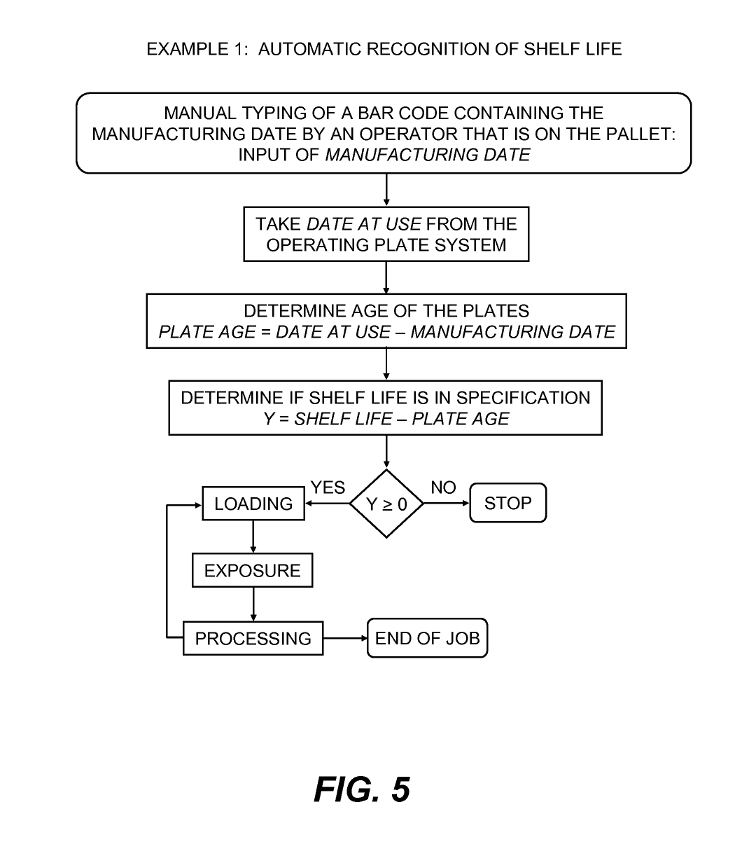

The detection of plate loading problems originating from plates positioned out of specification such as in using the precursor detection to evaluate if it is a slip sheet (has no precursor) or a plate and also maybe detect the position of the precursor to detect potential loading problems due to a misfeed of plates into the device and notify the customer to correct the position of the plates is eliminated through the use of the plate recognition system. The plate recognition system can be incorporated using a workflow such as that depicted in FIGS. 5-7 allowing recognition of the kind of the plate, wherein this occurs either manually or automatically by a collection device.

In one embodiment of the plate recognition system the information 60 that is collected by the sensing subsystem is transferred via the internet (WAN) or a local data base form the customer terminals to a web server which acts as a gateway to the host site local (LAN). The data collected are checked in the CONTOL CENTER Manger by a database (DATA I) making a decision whether correct loading of the plates occurs or not. In case of incorrect loading, the loading system stops the loading process while it continues with loading if the collected plate information equals with the information saved in DATA I. This embodiment of the system can optionally contain a QC-module collecting the information of the plates loaded and this data can be sent out for further QC control and rechecked with another database DATA II whether some actions could be necessary or not. Such actions could be the change of exposure energy based on manufacturing data. In addition, the fact to have the information of plates actually by a customer is very valuable for our QC department.

In one embodiment the system comprises a CONTROL CENTER based on a software receiving data about the plate either by manual collection (reading of a bar code by an operator or manual typing of the code by an operator) into the system of the CONTROL CENTER. Comparison of data received with those available in DATA I provided by the plate supplier allows to make a decision whether the plate is correctly loaded or not. Alternatively, plate data could be automatically transferred by a collection device into the CONTROL CENTER, which again makes a decision whether the plate is correctly loaded or not based on available information in DATA I. Such a system can have either manual or automatic plate information collection. It is also possible to have both integrated with the CONTROL CENTER while one collection method serves as a backup solution.

The automatic collection device collects data based on an integrated sensor which is able to read either a visually or hidden information (1D, 2D, or 3D code) about the kind of the plate or an RFID tag. It may also recognize the kind of the plate from a chemical point of view by comparing spectral data. The sensor device can read the plate information from top/back side of the plate or somewhere else from the pallet. The plate information collected comprises either the recognition of the plate by chemical/physical properties in a fingerprint pattern using destruction less method, which can occur either by employing absorption of electromagnetic waves located in the UV, visible, NIR or IR; by employing excitation techniques to sensor the information by emission techniques; and/or by employing scattering techniques to sensor properties such as reflection, scattering, or chemical information by Raman technique. This can be realized either by one method or a combination of at least two methods, that is the recognition of the plate by absorption of radio waves applying RFID technique, the recognition of the plate by a bar code that has either a 1D, 2D, or 3D pattern (holographic technique), or spectral information by using a special spectral device as shown in FIG. 2 for a system as shown in FIG. 3.

The set of precursor data could include, in one embodiment, precursor type, manufacturing date, or a plate property measured on a precursor sample in the same batch as the precursors. The set of imaging parameters can include a tonal value of a tint on an imaged and processed printing plate obtained from the precursor sample according to a standard set of imaging and processing settings and the imaging parameters that can be determined from the precursor data such as one or more of the plate pre-drum alignment settings, exposure energy and other relevant parameters such as plate surface depth, drum speed, resolution. These parameters include those used in plate processing systems such as in a media profile for square spot devices and LDA devices. Note that information such as surface depth, beam slope, beam curve etc are parameters that are determined according to the plates parameters also (such as thickness and type) as well as in the process of the head integration. The reason is that they are not the same for each head with the same plate type due to head performance variations. Thus in this system these parameters can be monitored, sensed and acted upon separately or in combination as required for optimum performance.

These parameters can be transferred automatically to a software application that controls the imaging devices if desired. Note that the set of processing parameters can include processor speed, developer temperature and developer conductivity and the codes can include an identification code and the interpreter retrieves the precursor data from a database record set associated with the identification code. The set of codes discussed above can additionally be interpreted according to an industry standard with or without using a proprietary database.

Examples of types of code carrier include an RFID tag or a hologram, a barcode and other similar markers. The code carrier can be located on the surface of each of the precursors opposite to the imageable layer and can be facing one or more directions, such as upward. In that case the separator sheet can be confirmed by the absence of the code carrier on the top surface of the stack and or the presence of the separator sheet can be further confirmed by a surface sensor capable of differentiating the surface of the separate sheet and the surface of the precursors opposite to the imageable layer. Additionally the imaging head can have a plurality of addressable channels each emitting a beam of radiation and the set of imaging parameters comprises the relative radiation strengths of the addressable channels where the relative strengths of the addressable channels are determined from the precursor data determined on a sample precursor from the same or a similar manufacturing batch. Alternatively the imaging head and a focusing device can be capable of focusing the imaging head onto the precursor, the set of imaging parameters comprises parameters for operating the focusing device, and the set of precursor data comprises a surface property of the precursor that affects the operation of the focusing device.

One preferred embodiment of the present invention is related to a method of making a printing plate from a lithographic plate precursor using a plate recognition system. The method starts with first providing a plurality of printing plate precursors (plate box or pallet with plates) having on each plate, plate box, or plate pallet information about the printing plate precursor in a form that it can be recognized by a plate recognition mean wherein the information about the printing plate precursor. This information can be referred to as a precursor data that includes information such as printing plate type, manufacturer, manufacturing date, plate dimension (length, width, thickness, information about web direction), plate type (Electra XD or Sword Ultra as traditional thermal plates, and photopolymer plates operating either with NIR and violet exposure such as ThermalNews Gold and VioletNews Gold, respectively, are some representative examples; other negative plates such as DTIP Gold or negative plates operating without preheat are alternatives as well), color of coating, reflectivity of coating surface and photosensitivity of the plate. The plate precursor data can be compiled in logical ways to yield a set of plate properties. Other data sometimes referred to as information can also be included such as plate parameters that relate to the imaging of the plate and possibly the plate precursor properties

The second step is to next provide the plurality of printing plates precursors in to equipment capable to imagewise exposure of printing plate precursor (platesetter). Then the third step involves transferring the information about the printing plate precursor by a recognition mean into the platesetter or the automation product that the platesetter works with and using the transferred information about the printing plate precursor in the platesetter for at least on operation selected from the group including one or more of the following:

a. Checking identity of the plate precursor and deciding whether plate precursor should be accepted or rejected by the platesetter.
b. Checking manufacturing date of the plate precursor and deciding whether the plate precursor should be accepted or rejected.
c. Checking plate precursor sensitivity and adjusting the exposure energy to the required level.
d. Checking plate precursor dimension (length, width and thickness) and using the information for adjusting the platesetter.
e. Using the information (plate precursor type, plate precursor dimension) for recording the plate consumption and using the records for initiation of plate order.
f. Verification of compatibility and adjustment of the processor speed to plate type.
g. Identification and discrimination of plate to all non plate cases (slip sheet, anodize, and emulsion).
h. Identification of the plate position inside the automation as means to inspect that the plates stack is positioned on the pallet according to the spec.

Finally the plate is imaged by exposing the plate precursor to the imaging subsystem. Optionally preheating, prewashing developing, rinsing, gumming, drying and post-baking the printing plate.

The plate recognition apparatus and system includes two main sub-systems, the sensing subsystem 17 which is responsible for the recognition of certain features and an authentication subsystem 62, including the interpreter 38. This plate recognition stores the collected data delivered using the sensing subsystem and compares this data to data stored in the data base in the authentication subsystem. According to the results of the comparison the software that controls the plate processing will accept or reject the plate and/or image data during one or more of the steps of loading, exposing, and processing of the plate in each stage of the workflow using the processor 26, which can monitor and/or adjust a number of physical parameters related to the operation of processor 26 based on the sensing and authentication subsystems.

FIG. 5 shows one embodiment of the system that automatically recognizes the shelf life of a plate. For example, when 1200 plates with a size of 894×453 mm are delivered on a pallet, they must be exposed and developed on a line that is equipped with an automatic plate loading system. An operator manually types the bar code containing the Manufacturing Date into the operating system, which also reads the actual Date at Use. From this data the system calculates the Plate Age when the plates are in use. In a further step, the system checks whether the plates fulfill the specification for the shelf life by subtracting the plate age from the Shelf Life resulting in a value Y. In this example this number is used to decide either to continue with loading, exposing and processing until the job is finished as long as Y≧0 or to stop if Y<0. The system, including controller(s) having interpreter software, calculates Y=5 days and decides to continue the job, which is finished after 1200 plates. Then the system reads the bar code from another pallet delivered with the same number and format. Calculation of Y results in −1, which directs the system to STOP further loading, and avoids loading of overage plates.

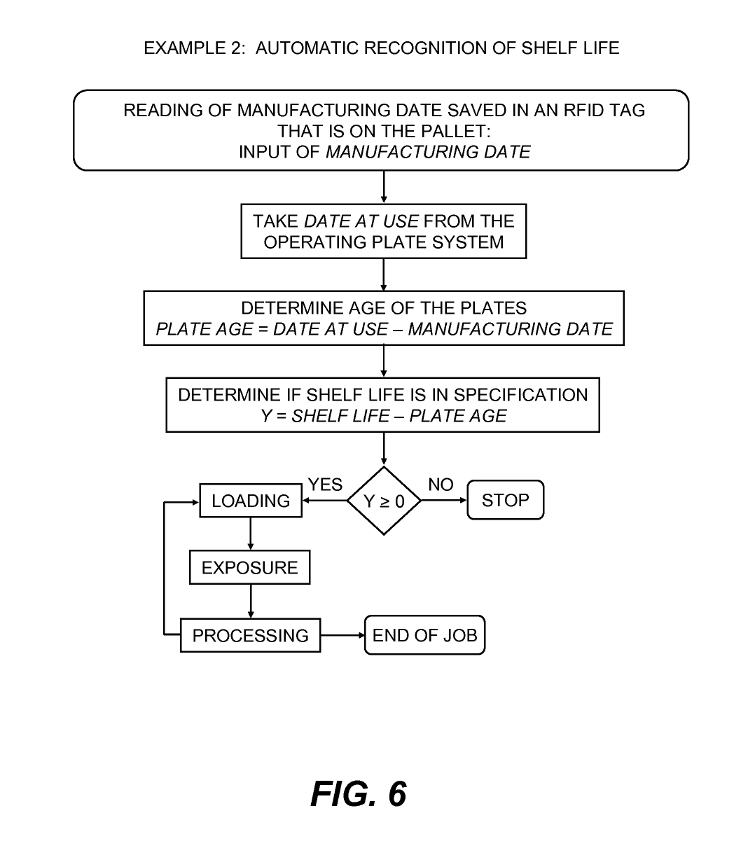

FIG. 6 shows another example of the system being used for automatic recognition of shelf life when 1200 plates with a size of 944×412 mm are delivered on a pallet, which bears an RFID tag. The plates must be exposed and developed on a line that is equipped with an automatic plate loading system. The RFID tag contains the Manufacturing Date, which is read into the operating system giving the actual Date at Use. In a consecutive step, the system reads when the plates are in use. From this data, the system calculates the Plate Age. In a further step, the system checks whether the plates fulfill the specification for the Shelf Life by subtracting the plate age from the shelf life resulting in a value Y. This number is used to decide either to continue with loading, exposing and processing until the job is finished as long as Y≧0 or to stop if Y<0. The system calculates Y=4 days and decides to continue the job, which is finished after 1200 plates. Then the system reads the bar code from another pallet delivered with the same number and format. Calculation of Y results in −2, which directs the system to STOP further loading, and avoids loading of over aged plates.

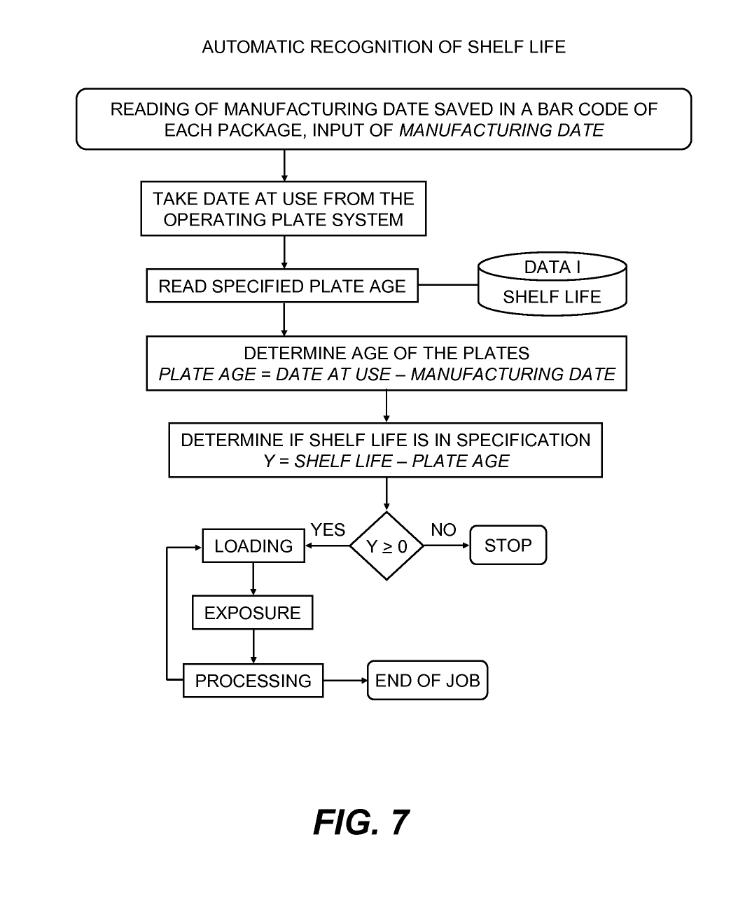

FIG. 7 shows an example of the system that automatically reads the bar code of a package with 100 plates of the size 531×309 mm. The bar code contains the Manufacturing Date. These plates must be exposed and developed on a line. In two consecutive steps, the system reads when the plates are in use and it also takes the Shelf Life from a database provided by the manufacturer. The database is actualized in periodic cycles by the manufacturer, which gives the benefit that changes of plate parameters, that is also the shelf life, can be actualized through a remote system directly at the customer. From this data, the system calculates the Plate Age. In a further step, the system checks whether the plates fulfill the specification for the Shelf Life by subtracting the Plate Age from the shelf life resulting in a value Y. This number is used to decide either to continue with loading, exposing and processing until the job is finished as long as Y≧0 or to stop if Y<0. The system calculates Y=100 days and decides to continue the job, which is finished after 100 plates. Then the system reads the bar code from another package delivered with the same number and format. Calculation of Y results in −1, which directs the system to STOP for further loading.

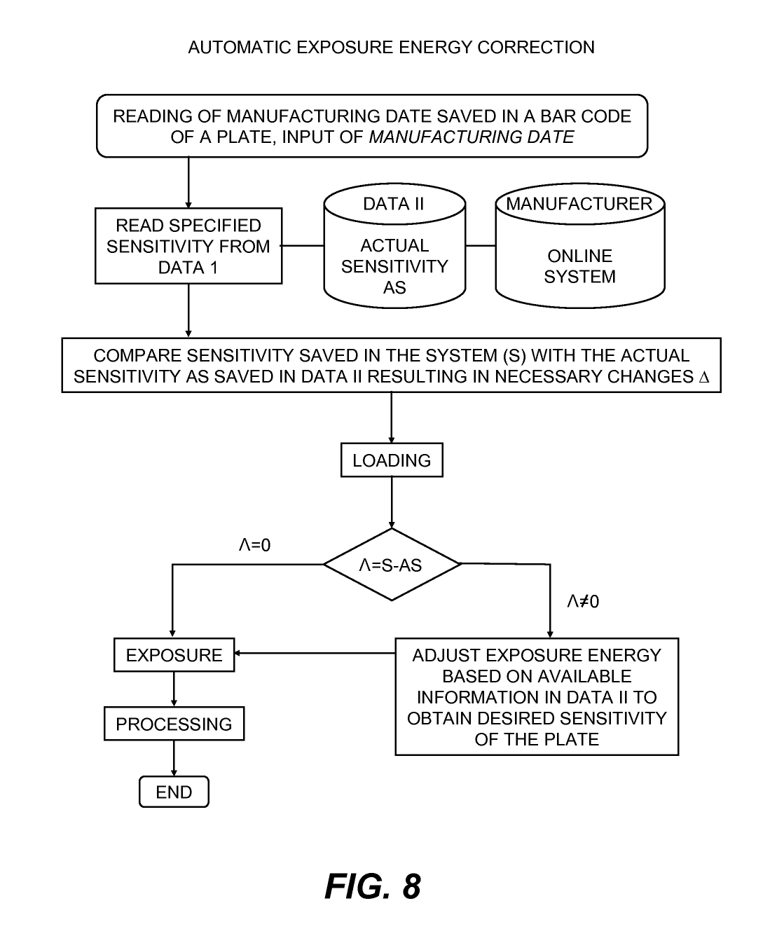

FIG. 8 shows the system with the capability to automatically correct exposure energy. The system automatically reads the bar code of a plate with the size 629×382 mm. The bar code contains the Manufacturing Date. This plate must be exposed and developed on a line. In two consecutive steps, the system reads when the plates are in use and it also takes the actual sensitivity a database (DATA II) provided by the manufacturers online system based on Manufacturing Date. The database is online actualized by the manufacturer, which gives the benefit that changes of plate parameters, that is also the exposure energy, can be actualized through a remote system directly at the customer. From this data, the system checks whether changes of the exposure energy are necessary by subtracting the actual sensitivity (AS) from the sensitivity saved in the system (S) resulting in Δ. In this example, S=70 mJ/cm² and reading of AS gives a Δ of 5 mJ/cm², meaning that the delivered plate is too fast. Then, the system loads a plate in a further step, reduces and exposes with the corrected energy to obtain the desired sensitivity. On the other side, no changes are necessary in the exposure setup if Δ=0. Thus, exposure energy is chosen in every based on Δ that would finally result in the desired sensitivity. In a consecutive step, the plate is processed. Under these circumstances, plates are more uniform processed because changes of plate parameters can be online adjusted.

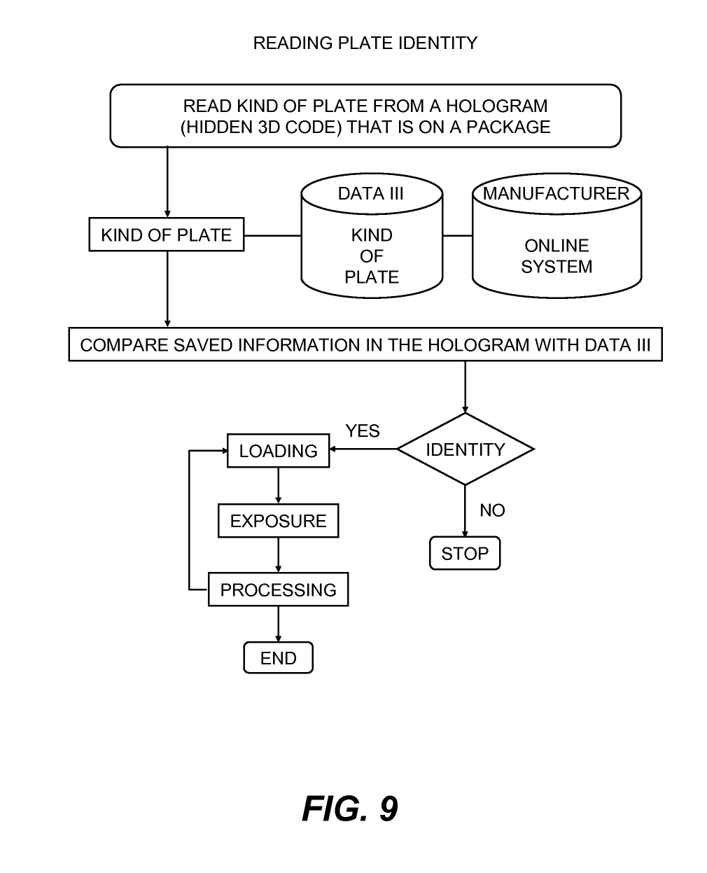

FIG. 9 shows an embodiment of the system for plate identification. In this embodiment the system automatically reads a hologram placed on a plate package having 100 plates with the size 612×355 mm. The hologram contains the plate identity and manufacturing date, which was written in three dimensions. These plates must be exposed and developed on a line. In a consecutive step, the system reads based on manufacturing date the kind of the plate from a database (DATA III), which contains the necessary encoded information in the same way as the information saved in the hologram. DATA III is online actualized by the manufacturer's online system. Then, both the information red from the hologram and the information obtained from DATA III are compared. In case that identity exists, the system continues with loading, exposing and processing until the job is finished. On the other side, it stops when no identity exists to avoid wrong loading.

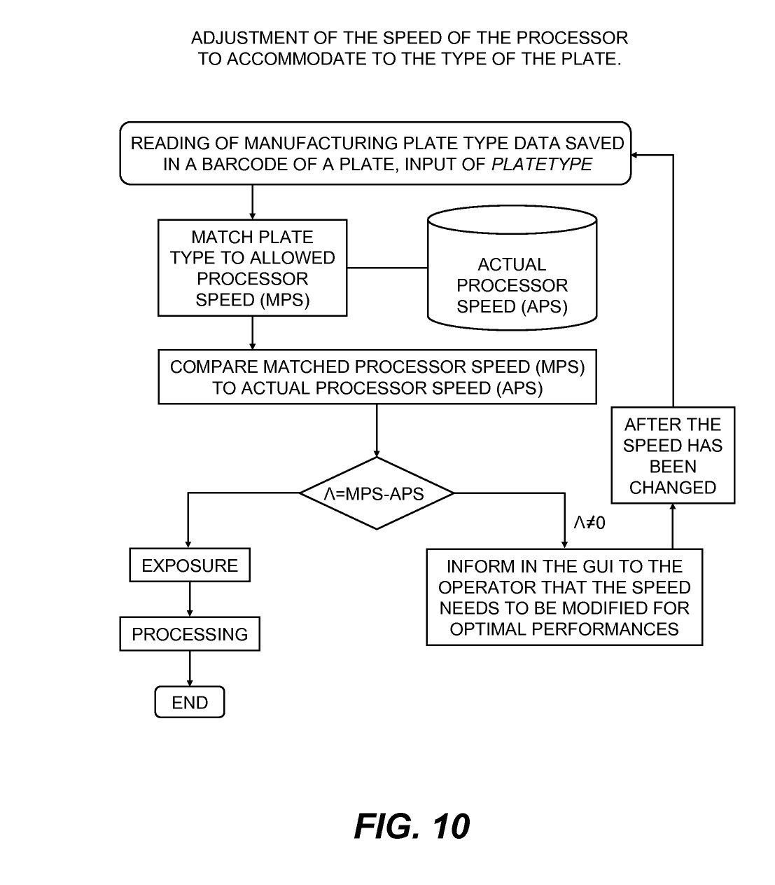

FIG. 10 shows an embodiment of the system that adjusts a processor speed based on a plate type. The system automatically reads the bar code of the plate. The bar code contains the plate type. The system then compares the type of plate to known type of plate's databases and according the type acquires the required speed of the processor. In case of incompatibility the system may indicate in the form of a message in the GUI that the speed of the processor is not the optimal speed or alter the speed of the processor to accommodate to the type of the plate.

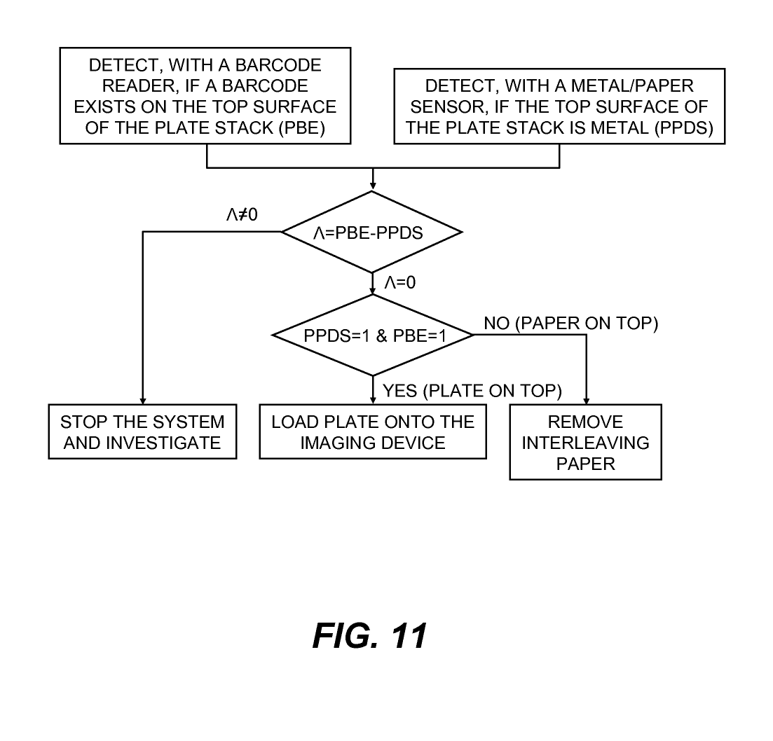

FIG. 11 shows an embodiment of the system for overcoming a problem commonly known as anodization problem. This problem is related to false identification of the top surface of a precursor stack by a metal/paper sensor and is caused by the anodizic oxide layer on the backside of the precursors (opposite to the side of the precursor support having an imageable layer). In this embodiment the backside of each plate precursor is printed with a barcode and the precursors are arranged into a stack with the backside of the precursor facing upward and separated from each other with a separate sheet. The system automatically checks the existence of the bar code of the plate on the top surface of the precursor stack and thereby creates a logical parameter PBE, which is set to 0 if the barcode is not found and set to 1 if the barcode is found. The system further senses the top surface of the precursor stack with a metal/paper sensor and creates another logical parameter PPDS, which is set to 0 if the metal/paper sensor detects paper surface and set to 1 if the metal/paper sensor detects metal. The system calculates the difference between PPE and PPDS, Λ=PPE−PPDS, stops the plate loading operation for further investigation if Λ≠0. If the Λ=0, the system will proceed to remove the separate sheet on top of the precursor stack if both PPE and PPDS equal to zero or load the precursor to the imaging device if both PPE and PPDS equal to one.

Those skilled in the art will appreciate that the conception on which this disclosure is based may readily be utilized as a basis for the design of other apparatus for carrying out the several purposes of the invention. It is most important, therefore, that this disclosure be regarded as including such equivalent apparatus as do not depart from the spirit and scope of the invention. The invention has been described in detail with particular reference to certain preferred embodiments thereof, but it will be understood that variations and modifications can be effected within the spirit and scope of the invention.

What is claimed is:

1. A method for preparing lithographic printing plates, comprising
a) providing a plurality of lithographic printing plate precursors each comprising at least one imageable layer,
b) qualifying the precursors according to a set of qualification criteria and a set of precursor data associated with the precursors
c) arranging the qualified precursors into a stack suitable for automatic loading of the precursors onto an imaging device and optionally having separator sheets inserted between two adjacent precursors,
d) removing the separator sheet if present at the top of the stack,
e) loading the precursor at the top of the stack onto the imaging device
f) image-wise exposing the precursor to form exposed areas and complementary non-exposed areas according to an image bitmap and a set of imaging parameters
g) optionally removing the imageable layer in the exposed or the complementary non-exposed areas using an automatic plate processor operating according to a set of processing parameters,
where the said set of precursor data is retrievable from an interpreter and a set of codes in a code carrier attached to the precursors or a packaging material for the precursors,
where steps 1) and 2) are repeated until qualified precursors become available to proceed to step 3), and steps 4) through 7) are repeated at least once.

2. A method of claim 1 where the said set of precursor data comprises precursor type, manufacturing date, or a plate property measured on a precursor sample in the same batch as the said precursors.

3. A method of claim 2 where the said property is the tonal value of a tint on an imaged and processed printing plate obtained from the said precursor sample according to a standard set of imaging and processing settings.

4. A method of claim 1 where the said set of imaging parameters is determined from the precursor data.

5. A method of claim 4 where the said set of imaging parameters comprises the plate pre-drum alignment settings.

6. A method of claim 4 where the said set of imaging parameters comprises the exposure energy.

7. A method of claim 4 where the said precursor data is transferred automatically to a software application that controls the imaging devices.

8. A method of claim 1 where the said set of processing parameters is determined from the precursor data.

9. A method of claim 8 where the said set of processing parameters comprises processor speed, developer temperature and developer conductivity.

10. A method of claim 1 where the said set of codes comprises an identification code and the said interpreter retrieves the precursor data from a database record set associated with the identification code.

11. A method of claim 1 where the said set of codes is interpretable into the precursor data according to an industry standard without using a proprietary database.

12. A method of claim 1 where the said code carrier is an RFID tag or a hologram.

13. A method of claim 1 where the said code carrier is a barcode.

14. A method of claim 1 where the code carrier is located on the surface of each of the precursors opposite to the imageable layer.

15. A method of claim 14 where the precursors are arranged into a stack with the surface having the code carrier facing upward.

16. A method of claim 15 where in step 4) the presence of the separator sheet is confirmed by absence of the code carrier on the top surface of the stack.

17. A method of claim 16 where in step 4) the presence of the separator sheet is further confirmed by a surface sensor capable of differentiating the surface of the separate sheet and the surface of the precursors opposite to the imageable layer.

18. A method of claim 4 where the imaging device comprises an imaging head having a plurality of addressable channels each emitting a beam of radiation and the said set of imaging parameters comprises the relative radiation strengths of the addressable channels.

19. A method of claim 18 where the relative strengths of the addressable channels are determined from the precursor data determined on a sample precursor from the same or a similar manufacturing batch.

20. A method of claim 4 where the imaging device comprises an imaging head and a focusing device capable of focusing the imaging head onto the precursor, the said set of imaging parameters comprises parameters for operating the focusing device, and the set of precursor data comprises a surface property of the precursor that affects the operation of the focusing device.
